(19) United States
(12) Patent Application Publication
(10) Pub. No.: US 2026/0177937 A1
(43) Pub. Date: Jun. 25, 2026

(54) METHOD FOR REWORKING AN OPTICAL ELEMENT, OPTICAL ELEMENT AND OPTICAL SYSTEM

(71) Applicant: Carl Zeiss SMT GmbH, Oberkochen (DE)

(72) Inventors: Michael GRUPP, Aalen (DE); Alexandra PAZIDIS, Woert (DE)

(21) Appl. No.: 19/545,084

(22) Filed: Feb. 20, 2026

Related U.S. Application Data
(63) Continuation of application No. PCT/EP2024/072239, filed on Aug. 6, 2024.

(30) Foreign Application Priority Data
Aug. 22, 2023 (DE) 10 2023 208 017.6

(51) Int. Cl. G03F 7/00; G01N 21/956

(52) U.S. Cl. CPC G03F 7/70975; G01N 21/956; G03F 7/7015; G03F 7/70266; G03F 7/70316; G03F 7/70958; G01N 2021/95676

(57) ABSTRACT

A method for reworking an optical element, in particular for microlithography, wherein the optical element has a first functional layer (203) which is optionally located on a figure individualised with figure processing for use in a first optical system or on an existing carrier layer (202). The method includes: over-coating the first functional layer (203) with an adjustment layer system (204), applying a carrier layer (205) onto the adjustment layer system (204), determining a setpoint wavefront effect for a new use of the optical element, carrying out a layer manipulation depending on the setpoint wavefront effect and applying a second functional layer (206) onto the carrier layer (205), wherein the optical element (200) is a lens or a wavefront correction element.

### CROSS REFERENCE TO RELATED APPLICATIONS

This is a Continuation of International Application PCT/EP2024/072239 which has an international filing date of Aug. 6, 2024, and the disclosure of which is incorporated in its entirety into the present Continuation by reference. This Continuation also claims foreign priority under 35 U.S.C. § 119 (a)-(d) to and also incorporates by reference, in its entirety, German Patent Application DE 10 2023 208 017.6 filed on Aug. 22, 2023.

### FIELD

The invention relates to a method for reworking an optical element, an optical element and an optical system, in particular for microlithography.

### BACKGROUND

Microlithography is used for producing microstructured components, such as for example integrated circuits or LCDs. The microlithography process is carried out in a so-called projection exposure apparatus comprising an illumination device and a projection lens. The image of a mask (=reticle) illuminated by the illumination device is projected in this case by the projection lens onto a substrate (for example a silicon wafer) that is coated with a light-sensitive layer (photoresist) and arranged in the image plane of the projection lens in order to transfer the mask structure to the light-sensitive coating of the substrate.

Mask inspection apparatuses are used for the inspection of reticles for microlithographic projection exposure apparatuses.

In projection lenses or inspection lenses designed for the extreme ultraviolet (EUV) range, i.e. at wavelengths of e.g. approximately 13.5 nm or approximately 6.7 nm, owing to the lack of availability of suitable light-transmissive refractive materials, reflective optical elements are used as optical components for the imaging process.

In the course of the development of projection lenses having an ever higher resolution capability and the attendant increasing accuracy requirements, carrying out the respective adjustment method in the course of which the respective optical system “is brought to specification” using the available degrees of freedom or manipulators also poses an increasingly more demanding challenge. Within the meaning of the present invention, “adjustment” is understood to mean the iterative reduction of the optical effects of process defects associated with the process for producing the optical system or the associated optical elements (e.g. grinding defects on lens elements, screwing effects on optical elements or the mounts thereof, etc.).

One problem that occurs in practice is the failure of optical elements (e.g. lens elements or mirrors), in particular after the above-described adjustment has already been carried out and after they have already been used in an optical system.

In this respect, it is feasible, in principle, to remove the relevant optical element to be repaired or reworked from the respective optical system and then firstly to “decoat” it (i.e. to remove a functional layer such as e.g. an anti-reflection (AR) coating typically present), in order then firstly to perform figure processing for the purpose of renewed individualization of the optical element and thus to adapt the optical element for the renewed use, whereupon a new functional layer could be applied and the optical element could be installed into either the previous optical system or a different optical system (i.e. a new optical system or an optical system to be overhauled).

However, especially with regard to decoating, either this procedure is associated with a comparatively high outlay or—and this applies to many optical elements in use, especially in microlithography—there are no suitable and reproducible decoating processes available at all, with the result that the method outlined above could not be used at all.

Therefore, for optical elements in microlithography that are fundamentally at risk of failure, a degree of stock-keeping for spare elements or complete systems has hitherto been required in practice, since on account of the complex production methods—often with the necessary additional integration of microelectronic and micromechanical components into the optical elements—an immediate new production only at the point of a sudden breakdown-dictated failure would lead to intolerable outage times of the apparatuses in the field with the attendant semiconductor production outages.

Such storage of optical elements or complete optical systems is associated with a considerable financial and logistical outlay in view of the complexity and value of the optical elements or systems used in microlithography and a trend toward increasing diversification of the elements, although the stock availability of an optical element that may be required due to a breakdown nevertheless cannot always be guaranteed under unfavorable conditions (e.g. a number of temporally concurrent failures of respectively identical elements).

Furthermore, the production of optical systems for microlithography—on account of the complex, highly accurate processing methods, inter alia—is associated with a high use of resources and hence a considerable CO₂ footprint (“carbon footprint”).

The ability of reprocessing optical elements that have previously already been in use and are to be individualized through figure processing with respect to the “new” optical system would thus be extremely advantageous both economically and ecologically, also in view of a potential reduction of the need for storage of spare elements that may never be required.

In respect of the prior art, reference is made merely by way of example to DE 10 2021 201 193 A1, U.S. Pat. Nos. 7,170,915 B2, 7,629,572 B2, 4,533,449, EP 3 286 595 B1 and WO 2017/125362 A1.

### SUMMARY

It is an object of the present invention to provide a method for reworking an optical element, an optical element and an optical system, in particular for microlithography, which enable a rework that is as time-saving, resource-conserving and reliable as possible. A further object is to avoid, at least partially, the problems described above.

According to one formulation, these objects are achieved in accordance with the features of the independent patent claims.

In accordance with one aspect, the invention relates to a method for reworking an optical element, in particular for microlithography, wherein the optical element has a first functional layer, and wherein the method includes:
a) overcoating the first functional layer with an adaptation layer system;
b) applying a carrier layer to the adaptation layer system;
c) determining a setpoint wavefront effect for a renewed use of the optical element;
d) optionally carrying out a layer manipulation on the optical element depending on the setpoint wavefront effect; and
e) applying a second functional layer on the carrier layer;
wherein the optical element is a lens element or a wavefront correction element.

One concept associated with the present invention is that an optical element which has a functional layer (optionally on an already existing, individualized figure or an individualized (existing) carrier layer) and has typically already been individualized for the implemented use in an optical system by figure processing is reworked so that no decoating (i.e. removal of the existing functional layer) is performed at all. Instead, an adaptation layer system with a new or further carrier layer is applied to the existing functional layer via an “overcoating”.

Depending on the requirements made of the optical element, it is also feasible that a layer manipulation can be dispensed with in certain cases, especially if the setpoint wavefront effect is already achieved without such a layer manipulation.

Against this background, step d) above is referred to as optional, but it will be expedient in the vast majority of cases.

The individualization or figure processing necessary for the renewed use of the relevant optical element in an optical system is then carried out according to the invention—if necessary—preferably on this “new” carrier layer, whereupon an additional new functional layer (e.g. antireflective coating) is then applied if necessary.

In addition to the abovementioned layers or layer systems, technically expedient or necessary intermediate layers, such as in particular adhesion promoting layers, can be provided. Such intermediate layers are possible e.g. between the first functional layer and the adaptation layer system, between individual or a plurality of layers of the adaptation layer system or between the adaptation layer system and the carrier layer or on the carrier layer.

By virtue of the adaptation layer system applied to the remaining first functional layer in conjunction with the carrier layer applied thereto, which can then be subjected to an individualizing layer manipulation, the required optical properties, in particular with regard to the anti-reflection effect, can be ensured despite decoating being dispensed with.

According to the invention, the method furthermore has the step of:
e) applying a second functional layer on the carrier layer.

The second functional layer can be in particular an AR (antireflection) layer.

In accordance with one embodiment, a layer design of the second functional layer is designed taking into account the existing first functional layer. In particular, the layer design of the second functional layer can be designed so that the cooperation of the first and second functional layers results in a predefined specification requirement being achieved by the optical element or the corresponding optical system in which the optical element is intended to be used after rework has taken place, for example with regard to the antireflective effect.

Preferably, in a wave mechanics consideration, the adaptation layer system is configured to the effect that the admittance of the first (i.e. non-removed) functional layer is adapted to the admittance of the carrier layer.

The adaptation layer system is preferably formed from a sequence of optical layers of predefined layer thickness with varying refractive index.

In accordance with one embodiment, step c) of determining the setpoint wavefront effect comprises ascertaining a system wavefront deviation between an existing system wavefront and a target system wavefront for an optical target system. In this case, the “adjustment concept” described in the introduction is realized in the sense of individualizing the optical element in adaptation to the setpoint system wavefront of the associated optical target system.

In accordance with one embodiment, the selection of the layer manipulation of the carrier layer depending on the setpoint wavefront effect is carried out using a previously ascertained lookup table, in which the respective wavefront effect of the optical element is listed for different layer manipulations of the carrier layer.

In accordance with one embodiment, the layer manipulation is carried out on the adaptation layer system and/or the carrier layer and/or on an optionally provided new, second functional layer.

In particular, however, the layer manipulation is carried out on the (new) carrier layer (which is preferably designed for a layer manipulation with regard to its thickness), since the performance of the adaptation layer system is not adversely affected in this case. Nevertheless, it would be feasible for a layer manipulation step—such as an ion implantation—also to extend gradually right into the region of the adaptation layer system. Furthermore, it would be feasible also to subject an optionally applied new, second functional layer alternatively or additionally to a layer manipulation.

In accordance with one embodiment, the layer manipulation comprises carrying out a locally varying layer removal.

In this case, during a layer manipulation on the carrier layer, the layer thickness of the carrier layer can preferably correspond at least to the expected maximum layer removal during the layer manipulation.

In accordance with one embodiment, the layer manipulation comprises carrying out a locally varying deposition of a layer material.

In accordance with one embodiment, the layer manipulation comprises carrying out a locally varying ion implantation.

In accordance with one embodiment, the carrier layer comprises silicon dioxide (SiO₂)—this is a preferred material in the case of lens elements— or silicon (Si)—this is a preferred material in the case of mirrors.

In accordance with one embodiment, carrying out a layer manipulation furthermore takes place such that one or more optical properties of the optical element from the following group of optical properties are obtained or optimized at the original level with only the first functional layer:
polarization effect with respect to reflection splitting and/or phase splitting, and/or
reflection effect, and/or
transmission effect.

In embodiments of the invention, the optical element is a lens element or a wavefront correction element, as known e.g. from DE 10 2017 206 256 A1.

In accordance with one embodiment, the optical element is designed for an operating wavelength of less than 250 nm, in particular less than 200 nm.

In accordance with one embodiment, the optical element is designed for an operating wavelength of less than 30 nm, in particular less than 15 nm.

In accordance with one embodiment, the optical system is a projection lens of a microlithographic projection exposure apparatus.

In accordance with a further embodiment, the optical system is a projection lens of a mask inspection apparatus.

In accordance with a further embodiment, the optical system can be an illuminator for a microlithographic projection exposure system, or some other optical component of such a system.

The invention further relates to an optical element, in particular for microlithography, which is formed by carrying out a method having the features described above, and to an optical system comprising such an optical element.

Further configurations of the invention can be gathered from the description and the dependent claims.

The invention is explained in greater detail below on the basis of exemplary embodiments illustrated in the accompanying figures.

### BRIEF DESCRIPTION OF THE DRAWINGS

In the figures:

FIG. 1 shows a flow diagram for explaining an exemplary sequence of a method according to the invention for reworking an optical element;

FIGS. 2A-2D show schematic illustrations for explaining a feasible sequence of a method according to the invention for reworking an optical element shown before (FIG. 2A) and during (FIG. 2B) application of an adaptive layer system, and during (FIG. 2C) and after (FIG. 2D) application of a second functional layer;

FIG. 3 shows a schematic illustration of a feasible arrangement of a microlithographic projection exposure apparatus designed for operation in the deep ultraviolet (DUV) wavelength range; and

FIG. 4 shows a schematic illustration of a feasible arrangement of a microlithographic projection exposure apparatus configured for operation in the EUV wavelength range.

### DETAILED DESCRIPTION

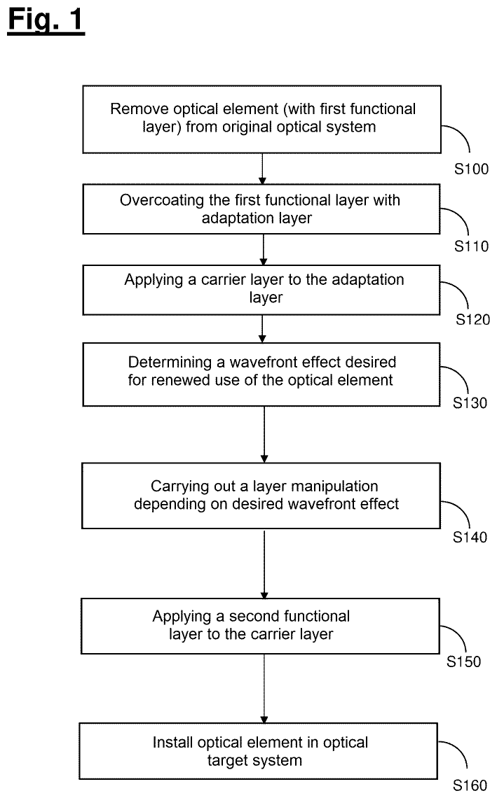

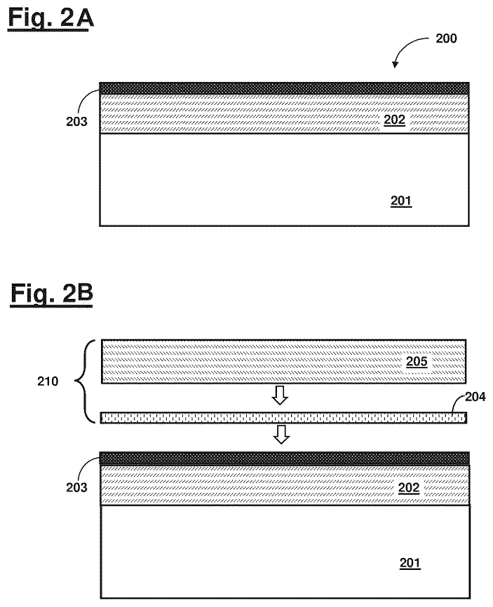

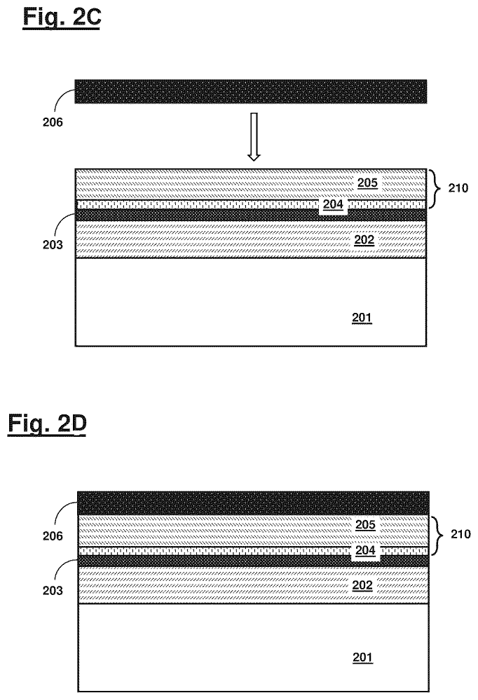

FIG. 1 shows a flow diagram for explaining a feasible sequence of a method according to the invention for reworking an optical element, wherein the individual method steps are in part additionally detailed in the schematic illustrations of FIGS. 2A-2D.

The starting point of an exemplary method according to the invention is the need for repair or rework of an optical element which had already been used in an optical system such as e.g. a projection lens of a microlithographic projection exposure apparatus or of a mask inspection system and had previously been individualized for this system (hereinafter referred to as “original optical system”) typically through figure processing. In the exemplary embodiment, this optical element, which is illustrated merely schematically and designated by 200 in FIG. 2A, has on a substrate 201 a first carrier layer 202 composed of silicon dioxide (SiO₂) and a first functional layer 203, which, depending on the type of optical element, can be e.g. an antireflective layer (AR layer). Further layers (not illustrated), e.g. adhesion promoter layers, can be provided in the layer structure.

After the removal of the optical element 200 from the original optical system in step S100, an overcoating of the first functional layer 203 with an adaptation layer system 204 is then carried out according to the invention in step S110, wherein a prior decoating or removal of the first functional layer 203 is explicitly dispensed with.

In step S120, a carrier layer 205 (in the example likewise composed of SiO₂) is applied to the adaptation layer system 204.

The additional layer structure that is composed of the adaptation layer system 204 and the carrier layer 205 and is applied overall in this way is referred to as adaptive layer system 210 in the context of the present invention (cf. FIGS. 2B-2D).

In a wave mechanics consideration, the adaptation layer system 204 adapts the admittance of the previous first functional layer 203 to the admittance of the carrier layer 205, which makes it possible to leave the first functional layer 203 in the layer structure without significantly adversely affecting the optical properties of the element 200 as a whole.

The adaptation layer system 204 preferably-even if this is not illustrated in specific detail in the schematic FIGS. 2A-2D-consists of a sequence of a plurality of layers of defined thickness each with different optical properties, in particular a varying, in particular alternating, refractive index.

The carrier layer 205 is preferably configured such that it allows a layer manipulation for subsequent individualization without significantly worsening the optical properties of the adaptation layer system 204 in the process.

If such a layer manipulation were introduced directly into the adaptation layer system 204, this would generally significantly adversely affect the adaptation performance thereof, by up to 10% in the case of typically required layer manipulations.

Therefore, in the adaptive layer system 210, there is preferably functional differentiation between an adaptation layer system 204 and the carrier layer 205, so that the quality of the adaptation does not change or changes only slightly even during required layer manipulations on the carrier layer 205.

The individualization required for the renewed use of the optical element 200 is now carried out on this carrier layer 205. For this purpose, firstly the setpoint wavefront effect of the optical element 200 in the relevant optical system in which the optical element 200 is intended to be used is ascertained (step S130) and then the layer manipulation suitable for achieving this wavefront effect is carried out on the carrier layer 205 (step S140).

Without the invention being restricted to this, the selection of this layer manipulation can be carried out in particular on the basis of a previously generated lookup table, in which the associated wavefront effect is listed for a multiplicity of different layer manipulations.

The layer manipulation itself can be carried out in various suitable ways and can comprise for example selective removal of layer material, in particular through ion beam figuring (IBF), selective or location-dependent deposition of layer material or doping with one or more further materials. The individualization or figure processing achieved with the layer manipulation can comprise in particular a suitable “aspherization” of the surface of the carrier layer.

The change in the layer thickness caused by the layer manipulation according to the invention can be carried out by way of example (and without the invention being restricted to this) so that the lateral thickness variation corresponds in terms of order of magnitude to a PV value (“peak to valley”) of 40 nm. For this purpose, the carrier layer 205 previously applied according to the invention and subjected to this layer manipulation can have from at least 100 nm.

Then, in accordance with FIG. 2C, a second functional layer 206 is applied to the carrier layer 205 in step S150 in accordance with FIG. 1. In this case, the presence of the previously overcoated first functional layer 203 is taken into account by the layer design of the second functional layer 206 being adapted accordingly. In other words, the second functional layer 206 is designed such that, in cooperation with the first functional layer 203, it ultimately satisfies the specification requirement.

A simple example of such a layer sequence could be manifested as shown in Table 1 below:

TABLE 1

| Seq. no. | QWOT | Material | Observation |
|---|---|---|---|
| 1 | substrate | substrate | |
| 2 | 1 | L | layer already existing in the |
| 3 | 1 | H | field |
| 4 | 1 | L | |
| 5 | 1.1 | L | adaptation layer system |
| 6 | 0.9 | H | |
| 7 | 1 | L | |
| 8 | 4 | carrier layer | SiO₂ or Si |
| | | (individualizable) | |
| 9 | 1 | L | new functional layer (AR |
| 10 | 1 | H | layer) |
| 11 | 1 | L | |

In the above layer sequence table, “QWOT” stands for the quarter wave optical thickness, L (Low) denotes a layer having a lower refractive index, e.g. composed of MgF₂, and H (High) denotes a layer having a higher refractive index, e.g. composed of LaF₃ or Al₂O₃.

In the above example, the adaptation layer system 204 is formed by the layers 5 to 7, and the carrier layer is formed by the layer 8, wherein the layers 5 to 8 overall form the adaptive layer system 210.

The carrier layer consists of SiO₂ upon use of the invention for lens element systems, or of silicon upon use for mirror systems.

Further expedient additional adhesion promoter layers are not illustrated.

The layer thicknesses for the adaptation layer (1.1 and 0.9) that deviate from the quarter wavelength QWOT=1 in the example allow adaptation to the “old” AR layer (first functional layer) over a certain angle of incidence range (in the example, this is an angle of incidence range of 0 to approx. 20°).

By using an even larger number of layers, the usable angle of incidence range can be increased or the adaptation and thus the antireflection effect can also be improved overall.

The determination of a suitable layer stack (number, materials, sequences and thicknesses) is expediently carried out using a computer-aided layer simulation with varying angles of incidence, wherein the above-described adaptation of the admittance represents a predefined constraint.

The exact admittance of the first functional layer and its angular behavior is generally known from the previous production process. If it is nevertheless not known, then the admittance of the contact medium of the first functional layer can be assumed as an approximation for antireflective layers.

In other words, generally the contact medium is the purge gas in the lithography system and the admittance is thus 1. Alternatively, the contact medium could also be the immersion liquid. The admittance thereof must then be used as a starting value.

From this starting point, the admittance of the carrier layer must then be targeted in the admittance diagram.

If the refractive index of the carrier layer is close to the refractive index of the optical element, the first functional layer can be applied approximately as an adaptation layer in reverse order. This is because an AR layer adapts the admittance of the lens element to the ambient medium. This means that the admittance profile is mirrored and thus lands near the initial value.

Since the admittance can only be accurately set for one wavelength and one angle at a time, however, changes in the adaptation layer design are normally still necessary, or it is often advisable to modify the design or to create a new design for the adaptation layer.

As a second functional layer, in principle the design of the first functional layer can be used if the refractive indices of the optical element and of the carrier layer are similar. Here as well, however, a new layer design will generally preferably be used.

The thickness of the (new) carrier layer is variable in principle and can be individualized through various processes, including figure processing, as described above, before the “new” AR layer (second functional layer) is applied.

In the example, the thickness of the carrier layer is a multiple of the thickness of the other layers of the adaptation layer system, in the example a quadruple quarter wavelength, that is to say a full wavelength, in which case this thickness, as already mentioned, can be varied to a certain extent without significant disadvantages for the adaptation efficiency.

If material-removing processing, such as in particular figure processing, is provided, the thickness of the carrier layer should expediently correspond to at least an expected maximum material removal during the layer manipulation (e.g. figure processing) or preferably exceed this amount.

FIG. 2D schematically shows the finished overcoated, individualized optical element provided with an adapted second functional layer 206, which optical element is installed in the setpoint optical system in the final step S160 in accordance with FIG. 1.

Without the invention being restricted to this, it is assumed that this system is a further system, which is referred to here as an “optical target system”.

In further embodiments, however, after the rework according to the invention the optical element can also be re-installed in the original optical system in which it had previously been used.

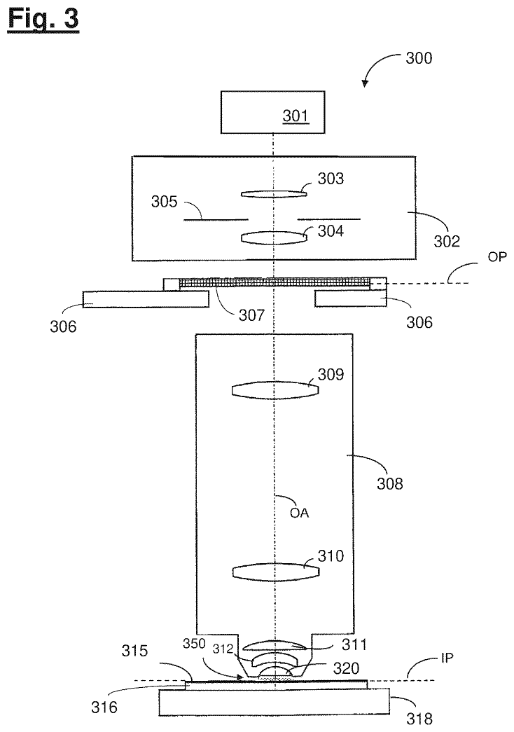

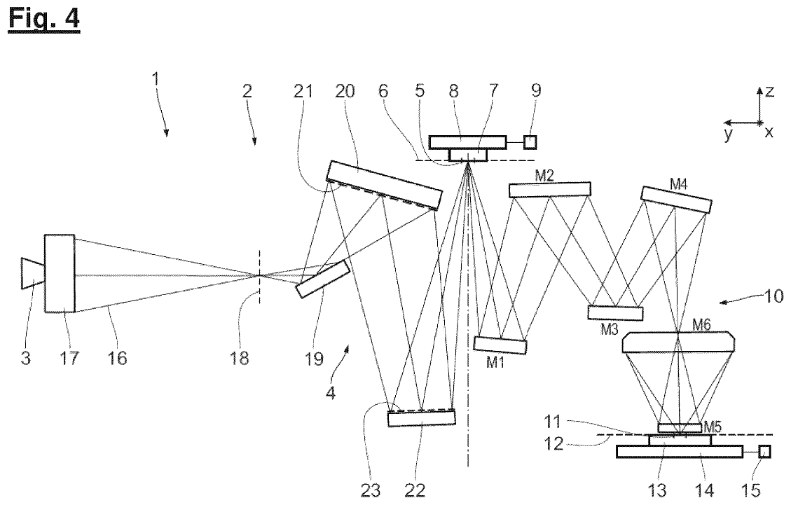

The optical system can be in particular a microlithographic optical system, and more particularly a projection lens or a component of an illuminator of a microlithographic projection exposure apparatus or of a mask inspection apparatus. Examples of a microlithographic projection exposure apparatus (designed for operation in the DUV and EUV wavelength ranges respectively) will be described below with reference to FIG. 3 and FIG. 4.

Furthermore, the layer design chosen in the exemplary embodiment corresponds to that of a lens element which is configured for operation in the DUV wavelength range or at a wavelength of approximately 193 nm. However, the invention is not restricted to that, but rather in further applications can also be realized in an optical element in the form of a mirror in particular for operation in the EUV (i.e. at wavelengths of less than 30 nm, in particular less than 15 nm) wavelength range.

FIG. 3 shows a schematic illustration of a feasible structure of a microlithographic projection exposure apparatus 300 which is designed for operation at wavelengths in the DUV range (i.e. for an operating wavelength of less than 250 nm, in particular less than 200 nm, e.g. approximately 193 nm) and comprises an illumination device 302 and a projection lens 308.

The illumination device 302, in which light from a light source 301 enters, is symbolized in highly simplified fashion by lens elements 303, 304 and a stop 305. In the example shown, the operating wavelength of the projection exposure apparatus 300 is 193 nm when using an ArF excimer laser as the light source 301. However, the operating wavelength can for example also be 248 nm when using a KrF excimer laser or 157 nm when using an F2 laser as the light source 301.

Between the illumination device 302 and the projection lens 308, a mask 307 is arranged in the object plane OP of the projection lens 308, this mask being held in the beam path by a mask holder 306. The mask 307 has a structure in the micrometers to nanometers range that is imaged, for example reduced by a factor of 4 or 5, onto an image plane IP of the projection lens 308 by the projection lens 308. The projection lens 308 comprises a lens element arrangement with which an optical axis OA is defined, this lens element arrangement likewise merely being symbolized in highly simplified fashion by lens elements 309, 310, 311, 312, 320.

A substrate 316, or a wafer, that has been provided with a light-sensitive layer 315 and positioned with a substrate holder 318 is held in the image plane IP of the projection lens 308. An immersion medium 350, which can be for example deionized water, is situated between the optical element 320 of the projection lens 308 that is located last on the image plane side and the light-sensitive layer 315.

FIG. 4 schematically shows in meridional section a feasible arrangement of a microlithographic projection exposure apparatus designed for operation in the EUV wavelength range.

In accordance with FIG. 4, the projection exposure apparatus 1 comprises an illumination device 2 and a projection lens 10. The illumination device 2 serves to illuminate an object field 5 in an object plane 6 with radiation from a radiation source 3 via an illumination optical unit 4. A reticle 7 arranged in the object field 5 is exposed hereby. The reticle 7 is held by a reticle holder 8. The reticle holder 8 is displaceable with a reticle displacement drive 9 in particular in a scanning direction. For explanation purposes, a Cartesian xyz-coordinate system is depicted in FIG. 4. The x-direction runs into the plane of the drawing. The y-direction runs horizontally, and the x-direction runs vertically. The scanning direction runs along the y-direction in FIG. 4. The z-direction runs perpendicularly to the object plane 6.

The projection lens 10 serves for imaging the object field 5 into an image field 11 in an image plane 12. A structure on the reticle 7 is imaged onto a light-sensitive layer of a wafer 13 arranged in the region of the image field 11 in the image plane 12. The wafer 13 is held by a wafer holder 14. The wafer holder 14 is displaceable with a wafer displacement drive 15 in particular along the y-direction. The displacement, firstly, of the reticle 7 by the reticle displacement drive 9 and, secondly, of the wafer 13 by the wafer displacement drive 15 can be synchronized with one another.

The radiation source 3 is an EUV radiation source. The radiation source 3 emits in particular EUV radiation, which is also referred to hereinafter as used radiation or illumination radiation. In particular, the used radiation has a wavelength in the range of between 5 nm and 30 nm. The radiation source 3 can be for example a plasma source, a synchrotron-based radiation source or a free electron laser (FEL). The illumination radiation 16 emanating from the radiation source 3 is focused by a collector 17 and propagates through an intermediate focus in an intermediate focal plane 18 into the illumination optical unit 4. The illumination optical unit 4 comprises a deflection mirror 19 and, arranged downstream thereof in the beam path, a first (field) facet mirror 20 (having schematically indicated facets 21) and a second (pupil) facet mirror 22 (having schematically indicated facets 23).

The projection lens 10 comprises a plurality of mirrors Mi (i=1, 2, . . . ), which are consecutively numbered according to their arrangement in the beam path of the projection exposure apparatus 1. In the example illustrated in FIG. 4, the projection lens 10 comprises six mirrors M1 to M6. Alternatives with four, eight, ten, twelve, or any other number of mirrors Mi are likewise possible. The penultimate mirror M5 and the last mirror M6 each have a through-opening for the illumination radiation 16. The projection lens 10 is a doubly obscured optical unit. The projection lens 10 has an image-side numerical aperture which, merely by way of example, can be greater than 0.5, in particular greater than 0.6, and can be for example 0.7 or 0.75.

The optical element subjected to the layer manipulation according to the invention can be for example one of the lens elements 309-312, 320 of the projection lens 308 from FIG. 3 or one of the mirrors M1 to M6 of the projection lens 10 from FIG. 4.

Even though the invention has been described on the basis of specific embodiments, numerous variations and alternative embodiments are evident to a person skilled in the art, e.g. through combination and/or exchange of features of individual embodiments. Accordingly, such variations and alternative embodiments are also encompassed by the present invention, and the scope of the invention is restricted only within the meaning of the accompanying patent claims and the equivalents thereof.

What is claimed is:

1. A method for reworking an optical element having a first functional layer having an admittance,
comprising:
overcoating the first functional layer with an adaptation layer system;
applying a carrier layer having an admittance to the adaptation layer system;
determining a setpoint wavefront effect for a renewed use of the optical element;
performing a layer manipulation on the optical element depending on the setpoint wavefront effect; and
applying a second functional layer on the carrier layer;
wherein the optical element is a lens element or a wavefront correction element and
wherein the adaptation layer system is configured such that the admittance of the first functional layer is adapted to the admittance of the carrier layer.

2. The method as claimed in claim 1, wherein the adaptation layer system is formed from a sequence of optical layers having predefined layer thicknesses and mutually varying refractive indices.

3. The method as claimed in claim 1, further comprising:
determining a layer configuration of the second functional layer in accordance with the first functional layer.

4. The method as claimed in claim 1, wherein said determining of the setpoint wavefront effect comprises ascertaining a system wavefront deviation between an existing system wavefront and a target system wavefront for an optical target system.

5. The method as claimed in claim 1, further comprising:
selecting the layer manipulation in accordance with the setpoint wavefront effect using a predetermined lookup table, in which respective wavefront effects of the optical element are listed for differing layer manipulations.

6. The method as claimed in claim 1, wherein the layer manipulation is performed on the adaptation layer system and/or on the carrier layer and/or on a new, second functional layer.

7. The method as claimed in claim 1, wherein the layer manipulation comprises performing a locally varying layer removal.

8. The method as claimed in claim 7, wherein the layer removal is performed on the carrier layer and a layer thickness of the carrier layer corresponds at least to an expected maximum layer removal during the layer manipulation.

9. The method as claimed in claim 1, wherein the layer manipulation comprises performing a locally varying deposition of a layer material.

10. The method as claimed in claim 1, wherein the layer manipulation comprises performing a locally varying ion implantation.

11. The method as claimed in claim 1, wherein the first functional layer of the optical element is located on an individualized figure or an existing carrier layer.

12. The method as claimed in claim 1, wherein the carrier layer comprises silicon dioxide (SiO₂) or silicon (Si).

13. The method as claimed in claim 1, wherein the layer manipulation furthermore takes place such that at least one optical property of the optical element from the following group of optical properties is adapted or optimized to values existing before carrying out the method:
polarization effect with respect to reflection splitting and/or phase splitting, and/or
reflection effect, and/or
transmission effect.

14. The method as claimed in claim 1, wherein the optical element is configured for an operating wavelength of less than 250 nm.

15. The method as claimed in claim 1, wherein the optical element is configured for an operating wavelength of less than 30 nm.

16. The method as claimed in claim 1, wherein the optical element is configured for a projection lens of a microlithographic projection exposure apparatus.

17. The method as claimed in claim 1, wherein the optical element is configured for a projection lens of a mask inspection apparatus.

18. The method as claimed in claim 1, wherein the optical component is an optical component of an illuminator of a microlithographic projection apparatus.
